(19) United States
(12) Patent Application Publication
(10) Pub. No.: US 2009/0145358 A1
(43) Pub. Date: Jun. 11, 2009

(54) DEPOSITION MATERIAL SUPPLYING MODULE AND THIN FILM DEPOSITION SYSTEM HAVING THE SAME

(75) Inventors: Kyoo Hwan Lee, Gyeonggi-do (KR); Dong Kwon Choi, Gyeonggi-do (KR); Chul Hwan Kim, Gyeonggi-do (KR); Suk Ju Park, Gyeonggi-do (KR); Hyung Sup Lee, Gyeonggi-do (KR)

Correspondence Address: HOSOON LEE, 9600 SW OAK ST. SUITE 525, TIGARD, OR, 97223, US

(73) Assignees: JUSUNG Engineering Co., Ltd, Gyeonggi-do (KR); ADS, Gyeonggi-do (KR)

(21) Appl. No.: 12/329,577

(22) Filed: Dec. 6, 2008

(30) Foreign Application Priority Data
Dec. 7, 2007 (KR) 10-2007-0126554
Mar. 27, 2008 (KR) 10-2008-0028353

(51) Int. Cl. C23C 16/00; B05B 7/00; C23C 14/00

(52) U.S. Cl. 118/720; 222/630; 118/50

(57) ABSTRACT

A deposition material supplying module includes a canister configured to define a storage space in which a deposition material is stored, a material flow controller provided with at least one groove receiving the deposition material supplied from the canister and adapted to rotate, and a carrier gas supplying unit configured to supply carrier gas to the material flow controller. The deposition material is filled in the groove and a fixed amount of the deposition material is supplied into the process chamber using the deposition material flow controller. Therefore, it is easy to control an amount of the deposition material supplied to the process chamber and the reliability on the fixed-quantity supply can be improved.

### CROSS-REFERENCE TO RELATED APPLICATION

This application claims priority to Korean Patent Application Nos. 10-2007-126554 filed on Dec. 7, 2007 and 10-2008-28353 filed on Mar. 27, 2008, and all the benefits accruing therefrom under 35 U.S.C. §119, the contents of which are incorporated by reference in their entirety.

### BACKGROUND

The present disclosure relates to a deposition material supplying module and a thin film deposition system having the module, and more particularly, to deposition material supplying module, which is designed to uniformly supply the deposition material into a process chamber, and a thin film deposition system having the module.

Generally, an organic film depositing apparatus is designed to form an organic film on a substrate by evaporating a powder type organic material. Such an organic film depositing apparatus includes a separate module for supplying the powder type organic material. A related art deposition material supplying module is designed to supplies the organic material to a film depositing chamber using a pressure difference between the deposition material supplying module and the film depositing chamber. Here, an amount of the organic material supplied to the film depositing chamber by the pressure difference between the deposition material supplying module and the film depositing chamber can be controlled in accordance with an amount of carrier gas supplied.

However, when the organic material is supplied to the film depositing chamber by the related art deposition material supplying module, reproducibility of an amount of the organic material supplied to the film depositing chamber is deteriorated by affects of an amount of the organic material remaining in a material storage chamber, a kind of the material, an amount of moisture contained in the material, static electricity, and the like.

### SUMMARY

The present disclosure provides a deposition material supplying module that is designed to uniformly supply a deposition material to a depositing chamber and a thin film deposition system having the deposition material supplying module.

In accordance with an exemplary embodiment of the present invention, a deposition material supplying module includes a canister configured to define a storage space in which a deposition material is stored, a material flow controller provided with at least one groove receiving the deposition material supplied from the canister and adapted to rotate, and a carrier gas supplying unit configured to supply carrier gas to the material flow controller.

The material flow controller may include a rotational body provided at a side thereof with the groove.

The material flow controller may include a rotational body and a plurality of teeth formed on the rotational body and spaced apart from each other, wherein the grooves are defined between the teeth.

The material flow controller may be disposed in a pipe provided with a rotating space in which the material flow controller rotates and configured to connect the canister to the depositing apparatus.

The pipe may have a first end connected to the canister and a second end connected to the depositing apparatus.

The deposition material supplying module may further include a carrier gas supplying pipe that is coupled to a side of the pipe to supply the carrier gas of the carrier gas supplying unit to the groove of the material flow controller.

The material flow controller may be installed at an intersection region of the pipe and the carrier gas supplying pipe in the rotating space of the pipe.

The teeth may be coupled on an outer circumference of the rotational body and spaced apart from each other at predetermined intervals to define the grooves between the teeth.

The grooves may be formed on an outer circumference and spaced apart from each other at predetermined intervals to define the teeth between the grooves.

The material flow controller may be disposed in a body provided with a rotating space and the canister storing the deposition material is disposed above the material flow controller in the body.

The deposition material supplying module may further include a first pipe connecting the canister to the material flow controller and a second pipe disposed under the material flow controller and communicating with the deposition apparatus.

The deposition material supplying module may further include a carrier gas supplying pipe that is coupled to a side of the second pipe to supply the carrier gas of the carrier gas supplying unit to the groove of the material flow controller.

The deposition material supplying module may further include a fixed-quantity support that is disposed under an end portion of the first pipe and configured to allow the deposition material to be filled in the groove as much as a volume of the groove.

The fixed-amount support may be disposed at a location toward which at least one of the grooves of the material flow controller filled with the deposition material moves and the tooth and groove may move immediately under the fixed-quantity support such that tops of the tooth and groove closely contact the fixed-quantity support.

The deposition material supplying module may further include a conveyer that is disposed to cover at least some of the teeth and grooves formed on the rotational body.

The conveyer belt may include a belt and rolling rods disposed at opposite ends of the belt.

The belt may rotate while circulating based on the rolling rods disposed on the opposite ends of the belt.

The belt may be disposed at a location toward which at least one of the grooves of the material flow controller filled with the deposition material moves and may be configured to rotate together with the rotational body by closing contacting the teeth formed on the rotational body.

The deposition material supplying module may further include at least one of an agitator or a vibrator that is disposed in the canister to agitate the deposition material and a filter configured to uniformly control an amount of the deposition material supplied from the canister to the material flow controller.

The agitator may include a power unit formed at a side of the canister, a shaft connected to the power unit, and one or more blades formed in a perpendicular direction to the shaft and spaced apart from each other.

The material flow controller may include a rotational shaft connected to the rotational body and a rotating member configured to rotate the rotational shaft.

In accordance with another exemplary embodiment of the present invention, a thin film deposition system includes a depositing apparatus configured to deposit a film and a deposition material supplying module configured to supply a deposition material to the depositing apparatus, wherein the deposition material supplying module includes a canister configured to define a storage space in which a deposition material is stored, a material flow controller provided with at least one groove receiving the deposition material supplied from the canister and adapted to rotate, and a carrier gas supplying unit configured to supply carrier gas to the material flow controller.

The thin film deposition system may further include a carrier gas storage unit configured to store the carrier gas and supply the carrier gas to the carrier gas supplying unit.

The thin film deposition system may further include a first pipe designed to connect the carrier gas storage unit to the carrier gas supplying unit, second and third pipes configured to connect the carrier gas supplying unit to the deposition material supplying module, and a first valve adapted to control communication between the second and third pipes.

The thin film deposition system may further include fourth and fifth pipes configured to connect the deposition material supplying module to the depositing apparatus and a second valve adapted to control communication between the fourth and fifth pipes.

### BRIEF DESCRIPTION OF THE DRAWINGS

Exemplary embodiments can be understood in more detail from the following description taken in conjunction with the accompanying drawings, in which:

FIG. 1 is a schematic view of a thin film deposition system in accordance with an exemplary embodiment;

FIGS. 2 and 3 are respectively side and top plane views of a deposition material supplying unit of the thin film deposition system of FIG. 1;

FIGS. 4 and 5 are views illustrating sequentially the operation of the deposition material supplying module of FIGS. 1 through 3;

FIG. 6 is a schematic view of a modified example of the deposition material supplying module of FIGS. 1 through 3;

FIG. 7 is a schematic view of another modified example of the deposition material supplying module of FIGS. 1 through 3.

FIG. 8 is a schematic view of a deposition material supplying unit in accordance with another exemplary embodiment of the present invention;

FIG. 9 is an enlarged view of a portion A of FIG. 8;

FIG. 10 is a schematic view of a modified example of a material flow controller of FIG. 9; and

FIG. 11 is an enlarged view of a portion B of FIG. 8.

### DETAILED DESCRIPTION OF EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Like reference numerals refer to like elements throughout.

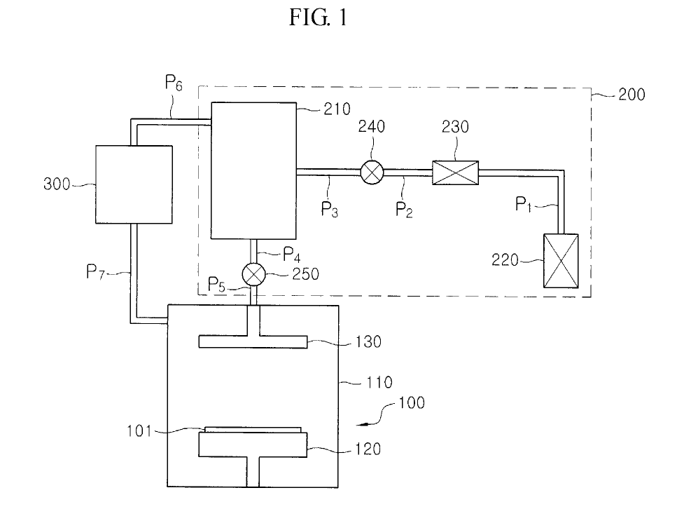

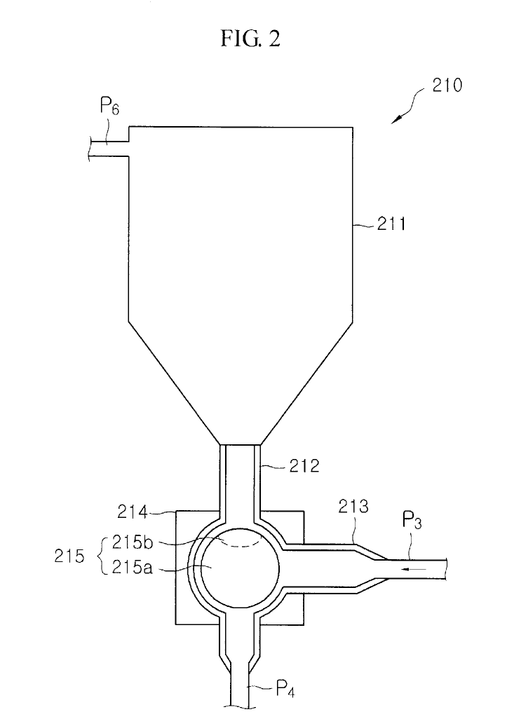

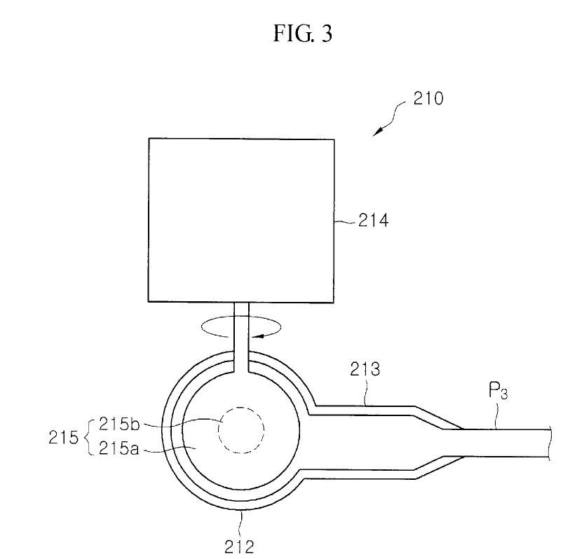

FIG. 1 is a schematic view of a thin film deposition system in accordance with an exemplary embodiment and FIGS. 2 and 3 are respectively side and top plane views of a deposition material supplying unit of the thin film deposition system of FIG. 1.

Referring to FIG. 1, a thin film deposition system in accordance with an exemplary embodiment includes a depositing apparatus forming a film on a substrate 101, a deposition material supplying module 200 supplying a powder type deposition material such as, for example, an organic material to the depositing apparatus 100, and a pressure controller 300 controlling pressure of not only the depositing apparatus 100 but also the deposition material supplying module 200.

The depositing apparatus 100 includes a chamber 110 defining a reaction space, a substrate supporting unit 120 that is disposed in the chamber 110 to support the substrate 101, and an injection unit 130 evaporating the powder type organic material supplied from the deposition material supplying module 200 and injecting the evaporated material to the substrate 101. Here, the injection unit 130 includes a heating member for evaporating the powder type organic material supplied to the injection unit 130. The evaporated organic material is injected into the reaction space defined by the chamber 110 through the injection unit 130 to form an organic film on the substrate 101. In addition, although not shown in the drawings, the depositing apparatus 100 may further include a rotating unit rotating the substrate supporting unit 120 or the injection unit 130. The chamber 110 may be provided at a side thereof with an inlet/outlet through which the substrate comes in and goes out.

The deposition material supplying module 200 includes a carrier storage unit 220 storing the carrier gas, a carrier gas supplying unit 230 supplying a predetermined amount of the carrier gas, a deposition material supplying unit 210 supplying the powder type organic material, a first valve 240 disposed between the carrier gas supplying unit 230 and the deposition material supplying unit 210, and a second valve 250 disposed between the deposition material supplying unit 210 and the depositing apparatus 100. In addition, the deposition material supplying module 200 further includes a plurality of pipes P1 to P5 interconnecting the carrier gas storage unit 220, carrier gas supplying unit 230, deposition material supplying unit 210, and depositing apparatus 100. The arrangement of the plurality of pipes will be described in more detail hereinafter.

The carrier gas storage unit 220 functions to store the carrier gas required for transferring the organic material to the chamber 110. The carrier gas supplying unit 230 receives a predetermined amount of the carrier gas from the carrier gas storage unit 220 and supplies the predetermined amount of the carrier gas to the deposition material supplying unit 210. To realize this, a mass flow controller (MFC) may be installed in the carrier gas supplying unit 230. The carrier gas storage unit 220 is connected to the carrier gas supplying unit 230 by the first pipe P1. The carrier gas supplying unit 230 is connected to the deposition material supplying unit 210 via the second pipe P2, first valve 240, and third pipe P3. At this point, the first valve 240 controls the communication between the second and third pipes P2 and P3. That is, only when the first valve 240 is turned on, the carrier gas is supplied to the deposition material supplying unit 210 through the third pipe P3. In addition, the deposition material supplying unit 210 is connected to the injection unit of the depositing apparatus 100 via the fourth pipe P4, second valve 250, and fifth pipe P5. At this point, the second valve 250 controls the communication between the fourth pipe P4 and the chamber 110. That is, only when the second valve 250 is turned on, the powder type deposition material is supplied to the injection unit 130 of the chamber 110. At least one of nitride (N2) gas, argon (Ar) gas, and helium (He) gas may be used as the carrier gas stored in the carrier gas storage unit 220.

The pressure controller 300 is connected to the deposition material supplying unit 210 via the sixth pipe P6 and connected to the chamber 110 via the seventh pipe P7 to control internal pressure of not only the deposition material supplying unit 210 but also the chamber 110.

The deposition material supplying unit 210 includes a canister 211 storing the powder type organic material, a pipe 212 disposed under the canister 211 and communicating with the injection unit 130 of the depositing apparatus 100, a material flow controller 215 disposed in a rotating space and supplying the organic material to the depositing material 100, and a carrier gas supplying pipe 213 connected to a side of the pipe 212 and supplying the carrier gas to the material flow controller 215. At this point, the fourth pipe P4 is connected between the pipe 212 and the injection unit 130 of the depositing unit 100 and the carrier gas supplying pipe 213 is connected to the carrier gas supplying unit 230 via the third pipe P3. In addition, although not shown in the drawings, the deposition material supplying unit 210 is provided with a material injection hole through which the powder type organic material is supplied as necessary. That is, the organic material may be additionally supplied by opening the material injection hole in accordance with an amount of the organic material in the canister 211. In this case, the additional supplying of the organic material may be done with the whole system stops operating. However, the present invention is not limited to this. That is, when a plurality of the deposition material supplying units 210 are provided in the deposition material supplying module 200, the organic material can be additionally supplied without stopping the process.

The canister 211 serves to store the powder type organic material. The canister 211 is designed to have a pentagonal section. That is, the canister 211 includes a circular or polygonal tub type upper portion and a circular or polygonal cone type lower portion. Here, the canister 211 may be formed to have an inclined portion adjacent to the pipe 212 such that the powder type organic material can be collected at a lower portion of the canister 211 communicating with the pipe 212. In addition, although not in the drawings, a shutter may be provided in the pipe 212 so that the powder type organic material stored in the canister 211 can be transferred to the material flow controller 215 only when the pipe 212 is opened by the shutter. Needless to say, the canister 211 is not limited to this configuration. That is, the canister 211 may be formed in a variety of shapes. For example, the canister 211 may be formed in a cone-shape having a width that is gradually reduced as it goes toward the pipe 212. The sixth pipe P6 connected to the pressure controller 300 is connected to a side of the canister 211. As previously described, the sixth pipe P6 is connected to the pressure controller 300 to control pressure between the canister 211 and an interior of the chamber 110 of the depositing apparatus 100.

Here, as previously described, the pipe 212 has a first end connected to the canister 211 and a second end is connected to the fourth pipe P4 communicating with the injection unit 130 of the depositing apparatus 100. The carrier gas supplying pipe 213 is connected to a side of the pipe 212. In this embodiment, the pipe 212 and the carrier gas supplying pipe 213 are arranged to generally define a T-shape. However, the arrangement is not limited to this configuration. In addition, the carrier gas supplying pipe 213 communicates with the third pipe P3 connected to the carrier gas supplying unit 230.

The material flow controller 215 includes a rotational body 215a and a groove 215b formed on a side of the rotational body 215a. However, the material flow controller 215 is not limited to this. The groove 215b is formed in a variety of sizes and shapes to store the powder type organic material supplied from the canister 211. In this embodiment, the groove 215b is formed in a hemispherical shape. However, the present invention is not limited to this. The groove 215b may be formed in a variety of shapes storing the organic material. Further, one or more grooves 215b are formed on the rotational body 215a.

The material flow controller 215 is disposed in a region where the pipe 212 intersects the carrier gas supplying pipe 213. A driving unit 214 is installed at one end of the material flow controller 215. The driving unit 214 servers to rotate the material flow controller 215. The driving unit 214 includes a rotational shaft (not shown) connected to the rotational body 215a and a rotating member rotating the rotational shaft. At this point, the rotating member is not limited to a specific unit. For example, a motor may be used as the rotating member. In addition, the driving unit 214 controls an RPM of the rotating body 215a such that a time for exposing the groove 215b formed on the rotating body 215a to a lower portion of the canister 211 in accordance with the RPM of the rotating body 215a. By doing this, an amount of the organic material filled in the groove 215b can be controller. Accordingly, when the organic material is supplied from the canister 211, the organic material is filled in the groove 215b of the material flow controller 215. After this, the material flow controller 215 rotates by the driving unit 214. A fixed amount of the organic material, which corresponds to the volume of the groove 215b, always remains in the grooves 215b by the friction that is generated between the organic material flow controller 215 and the pipe 212 as the material flow controller rotates. Accordingly, a uniform amount of the organic material is supplied to the injection unit 130 of the depositing apparatus 100.

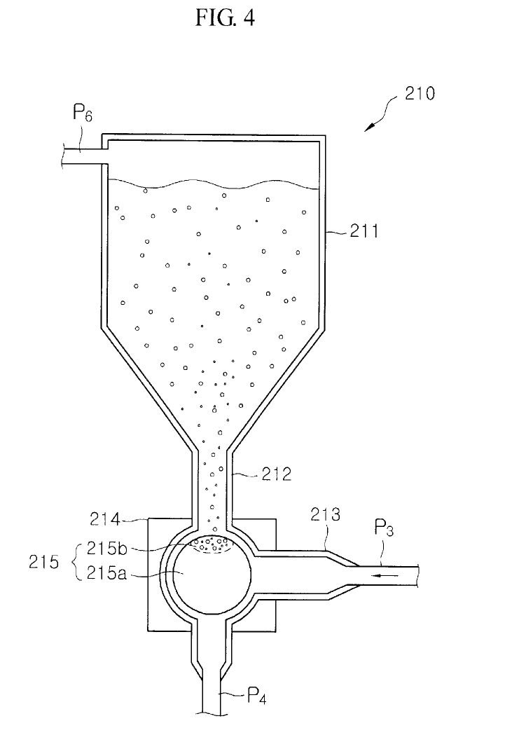

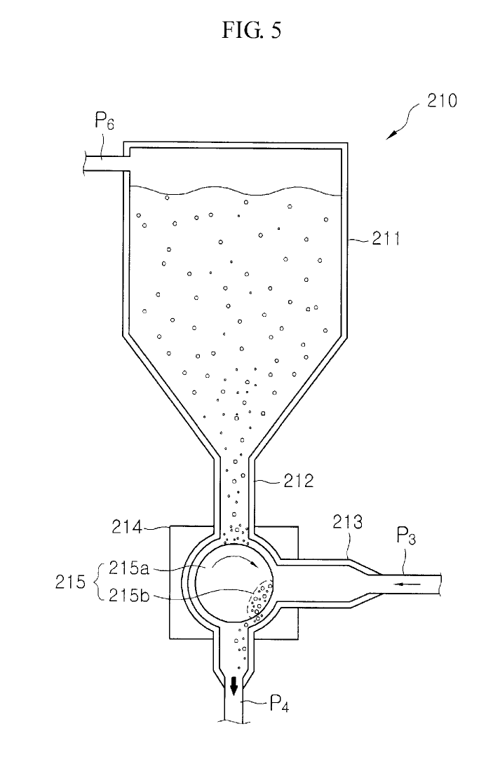

FIGS. 4 and 5 are views illustrating sequentially the operation of the deposition material supplying module of FIGS. 1 through 3.

First, the powder type organic material stored in the canister 211 is supplied to the groove 215b of the material flow controller 215 through the pipe 212. When the organic material is filled in the groove 215b, the driving unit 214 operates. At this point, the material flow controller 215 makes friction with an inner wall of the pipe 212 and thus the groove 215b is filled with the organic material as much as its volume.

Further, as the material flow controller 215 rotates and thus some of the grooves 215b pass through a region to which the carrier gas supplying pipe 213 is connected, the carrier gas of the carrier gas supplying unit 230 is supplied to the carrier gas supplying pipe 213 through the third pipe P3. At this point, the carrier gas is injected to the groove 215b filled with the organic material and thus the organic material is separated from the groove 215b. Further, the organic material is supplied to the injection unit 130 of the depositing apparatus via the fourth pipe P4.

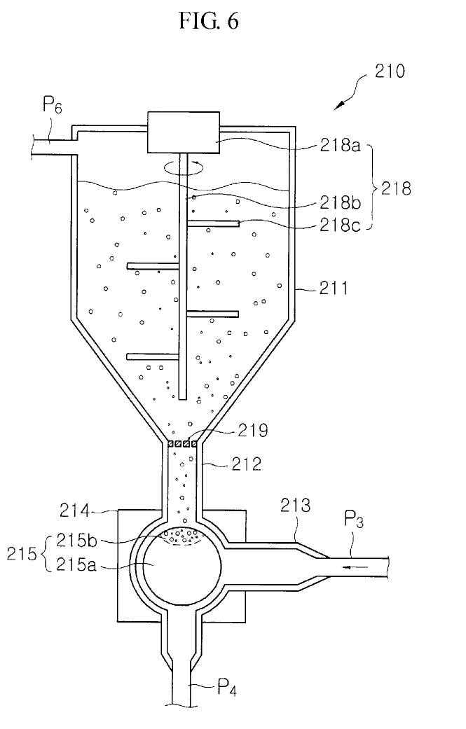

FIG. 6 is a schematic view of a modified example of the deposition material supplying module of FIGS. 1 through 3. In this modified example, parts identical to those of FIGS. 1 through 3 will not be described or be briefly described.

Referring to FIG. 6, a deposition material supplying unit 210 includes a canister 211 storing the powder type organic material, a pipe 212 correspondingly disposed under the canister 211 and communicating with an injection unit of a depositing apparatus 100, a material flow controller 215 disposed in a rotational space of the pipe 212 and supplying the organic material to the depositing apparatus 100, and a carrier gas supplying pipe 213 connected to a side of the pipe 212 and supplying the carrier gas to the material flow controller 215. The deposition material supplying unit 210 of this modified example further includes an agitating unit 218 disposed inside the canister 211 to agitate the organic material and a filter 219 disposed at a region where the canister 211 and the pipe 212 are adjacent to each other.

The canister 211 serves to store the powder type organic material. The canister 211 is designed to have a pentagonal section. That is, the canister 211 includes a circular or polygonal tub type upper portion and a circular or polygonal cone type lower portion. Here, the canister 211 may be formed to have an inclined portion adjacent to the pipe 212 such that the powder type organic material can be collected at a lower portion of the canister 211 communicating with the pipe 212. In this embodiment, the pipe 212 and the carrier gas supplying pipe 213 are arranged to generally define a T-shape. However, the arrangement is not limited to this configuration.

The material flow controller 215 includes a rotational body 215a and a groove 215b formed on a side of the rotational body 215a. The material flow controller 215 is disposed in a region where the pipe 212 intersects the carrier gas supplying pipe 213.

The agitating unit 218 includes a power unit 218a, a shaft 218b connected to the power unit 218a, and agitating blades 218c installed on the shaft 218b and spaced apart from each other. The agitating unit 218 agitates the powder type deposition material stored in the canister 211 so that the material can be effectively moved in the canister 211. The power unit 218a may be installed on a side of the canister 211, i.e., on an upper shaft. The shaft 218b has a first end connected to the power unit 218a. The agitating blades 218c are connected to the shaft 218b in an intersection direction and spaced apart from each other at predetermined intervals.

The filter 219 is disposed at a region where the canister 211 and the pipe 212 are adjacent to each other. An amount of the organic material supplied from the canister 211 to the material flow controller 215 is uniformly controlled through the filter 219. The filter 219 is formed to have a plurality of apertures or slits.

In this modified example, in order to effectively supply the powder type deposition material stored in the canister 211 to the material flow controller 215, the agitating unit 218 is further installed. However, the present invention is not limited to this. For example, instead of the agitating unit, a vibrator may be used.

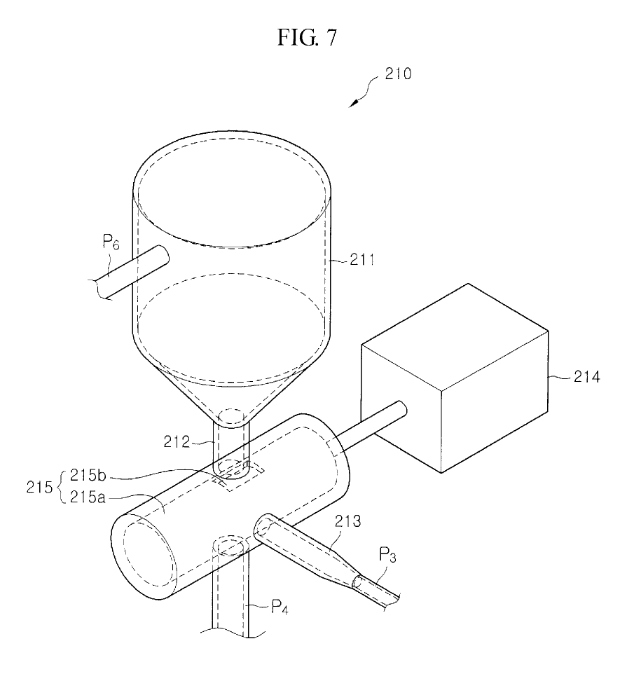

FIG. 7 is a schematic view of another modified example of the deposition material supplying module of FIGS. 1 through 3.

Referring to FIG. 7, the material flow controller 215 includes a rotational body 215a and a groove 215b formed on a side of the rotational body 215a. The rotational body 215a is formed in a cylindrical shape and a part of the pipe 212 is formed in a shape (i.e., a cylindrical shape) corresponding to the rotational body 215a. In addition, the groove 215b is formed in a variety of sizes and shapes to store the powder type organic material supplied from the canister 211. Further, one or more grooves 215b are formed on the rotational body 215a. The material flow controller 215 is disposed in a region where the pipe 212 intersects the carrier gas supplying pipe 213.

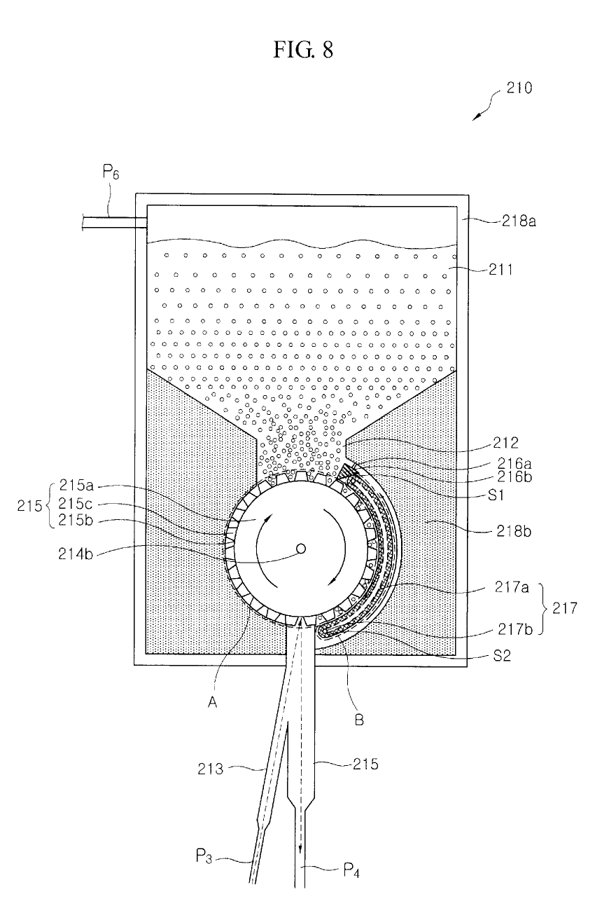

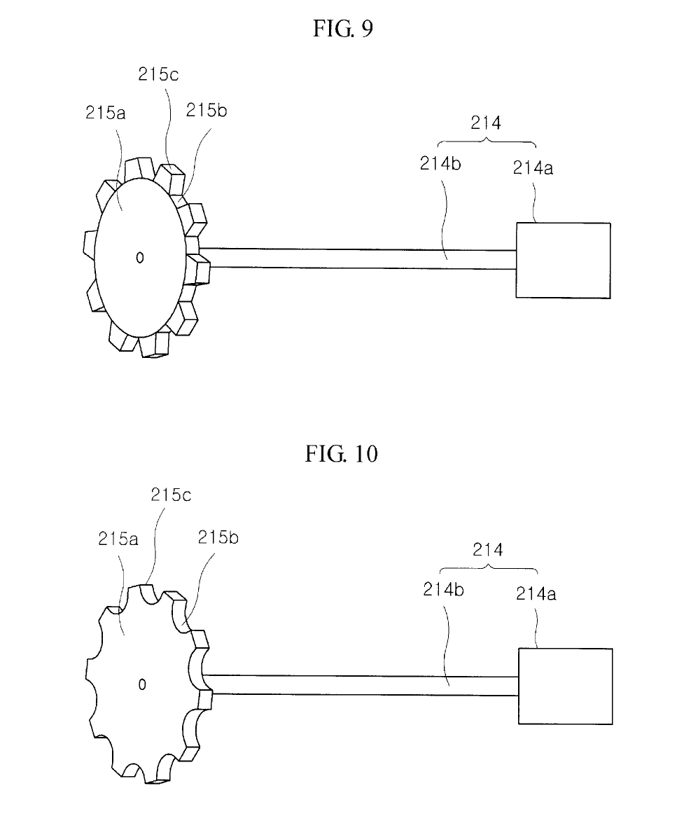

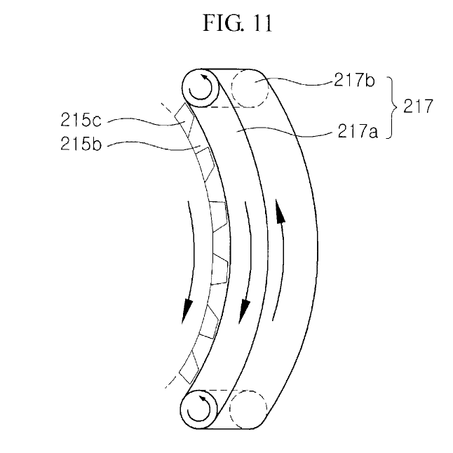

FIG. 8 is a schematic view of a deposition material supplying unit in accordance with another exemplary embodiment of the present invention. FIG. 9 is an enlarged view of a portion A of FIG. 8. FIG. 10 is a schematic view of a modified example of a material flow controller of FIG. 9. FIG. 11 is an enlarged view of a portion B of FIG. 8.

Referring to FIG. 8, a deposition material supplying unit 210 includes a body 218a defining an interior space, a canister 211 disposed in the interior space of the body 218a and storing the powder type organic material, a first pipe communicating with a lower portion of the canister 211, a material flow controller 215 communicating with a lower portion of the first pipe 212 and supplying the organic material to the depositing apparatus 100, and a second pipe 215 correspondingly disposed under the material flow controller 215 and supplying the organic material stored in the material flow controller 215 to the depositing apparatus 100. Further, the deposition material supplying unit 210 further includes caps 218b enclosing the material flow controller 215, a fixed-quantity support 216b disposed under an end of the first pipe 212, and a conveyer 217 disposed between the cap 218b and the material flow controller 215. Here, a carrier gas supplying pipe 213 is connected to a side of the second pipe 215 to supply the carrier gas to the second pipe 215. Here, the carrier gas supplying pipe 213 is connected to the carrier gas supplying unit 230 through a third pipe P3. In addition, the deposition material supplying unit 210 is provided with a material inlet (not shown) through which the powder type organic material is supplied as necessary.

The canister 211 is located at an upper region of the interior space of the body 218a. Further, the canister 211 is designed to have a pentagonal section. That is, the canister 211 includes a circular or polygonal tub type upper portion and a circular or polygonal cone type lower portion. In addition, the first pipe 212 is disposed under the canister 211. At this point, the canister is formed in a shape having a width that is gradually reduced as it goes toward the first pipe 212. By this structure, the powder type organic material is collected right above the first pipe 212. However, the present invention is not limited to this configuration. The canister 211 may be formed in a variety of shapes. That is, the canister 211 may be formed in a cone shape having a width that is gradually reduced toward the first pipe 212. Although not shown in the drawings, an agitating unit or a vibrator for mixing the organic material may be provided in the canister 211 to prevent the organic material from being massed into a lump.

The material flow controller 215 serves to continuously supply a predetermined amount of the organic material to the second pipe 215. As shown in FIGS. 8 and 9, the material flow controller 215 is formed in a saw-toothed wheel shape. That is, the material flow controller 215 includes a rotational body 215a, a plurality of teeth formed on the rotational body 215a, grooves 215b defined between the teeth 215c. The material flow controller 215 may rotate by a driving unit 214.

The rotational body 215a is formed in a cylindrical shape. The plurality of the teeth 215c are coupled on a circumference of the rotational body 215a. At this point, the teeth 215c protrude on the top surface of the rotational body 215a and spaced apart from each other at an identical interval. At this point, a size of each groove 215b may vary in accordance with an interval between the adjacent teeth and a size of each of the teeth 215c. Therefore, an amount of the organic material filled in the groove 215b can be varied in accordance with the size of the groove 215b and thus an amount of the organic material supplied to the second pipe 215 can be varied. Here, each of the teeth has a trapezoidal section. However, the present invention is not limited to this configuration. For example, the tooth 215c may be formed to have a semi-circular section or polygonal section.

As shown in FIG. 9, the material flow controller 215 is formed such that the teeth 215c are formed on the circumference of the rotational body 215a to form the grooves 215b between the teeth 215c. However, the material flow controller 215 is not limited to this configuration but formed in a variety of shapes. That is, as shown in FIG. 10, a plurality of grooves 215b are formed on a circumference of the rotational body 215a and spaced apart from each other at predetermined intervals.

The driving unit 214 rotates the rotational body 215a provided with the grooves 215 to supply the organic material to the second pipe 215. As shown in FIGS. 9 and 10, the driving unit 214 includes a rotational shaft 214b connected to the rotational body 215a, and a rotating member 214a rotating the rotational shaft 214b. At this point, any means for rotating the rotating shaft 214b can be used as the rotating member 214a. For example, a motor may be used as the rotating member 214a. When the rotational shaft 214b rotates by the rotating member 214a, the rotational body 215a rotates by the rotational shaft 214b. Further, the rotational shaft 214b connected to the material flow controller 215 may project out of the body 218a over the body unit 218a. At this point, the rotating member 214a may be connected to an outer end of the projection portion projecting out of the body 218a.

The driving unit 214 controls an RPM of the rotating body 215a such that a time for exposing the groove 215b formed on the rotating body 215a to the first pipe 212 in accordance with the RPM of the rotating body 215a. By doing this, an amount of the organic material filled in the groove 215b can be controlled by controlling the RPM of the rotational body 215a. After this, by rotating the rotational body 215a using the driving unit 214, the groove 215b filled with the organic material is exposed above the second pipe 215 to supply the organic material to the second pipe 215. By sequentially repeating the above-described processes, a fixed amount of the organic material can be continuously supplied to the second pipe 215.

The second pipe 215 is disposed under the material flow controller 215, receives the organic material filled in the grooves 215b of the material flow controller 215, and supplies the organic material to the chamber 110. At this point, it is more effective to at least one of the grooves 215b filled with the organic material is exposed above the second pipe 215 by rotating the rotational body 215a using the driving unit 214. In addition, the second pipe 215 is connected to the injection unit 130 of the chamber 110 through the fourth pipe P4. Therefore, the organic material supplied through the material flow controller 215 can be supplied to the injection unit 130 of the chamber 110 via the second pipe 215 and the fourth pipe P4.

Further, the carrier gas supplying pipe 213 is connected to a side of the second pipe 215 to supply the carrier gas into the second pipe 215. However, the present invention is not limited to this. For example, the carrier gas supplying pipe 213 may be connected to an end portion of the second pipe 215 through the cap 218b. Here, the carrier gas supplying pipe 213 is connected to the carrier gas supplying unit 230 through the third pipe P3. The flowing direction of the carrier gas is determined depending on an arrangement of the carrier gas supplying pipe 213. The carrier gas supplying pipe 213 is arranged such that the carrier gas can be injective immediately above the second pipe 215. That is, the carrier gas supplying pipe 213 is disposed right above the second pipe 215 to supply the carrier gas to the groove 215b filled with the organic material. By this arrangement, when the carrier gas is injected to the grooves 215b filled with the organic material and located immediately above the second pipe 215, the organic material is separated from the groove 215b by the injection pressure of the carrier gas. At this point, since the second pipe 215 communicates with the injection unit 130 of the chamber 110 through the fourth pipe P4, thee organic material supplied to the second pipe 215 is supplied to the injection unit 130 of the chamber 110 along the carrier gas.

The caps 218b are disposed to enclose the rotational body 215a provided with the grooves 215b, defining a rotational space for the rotational body 215a. Here, the caps 218b are disposed to enclose the rotational body 215a relative to a region except for the first and second pipes 212 and 215 with reference to the first and second pipes 212 and 215. Therefore, the rotational body 215a provided with the grooves 215b can rotate in the rotational space of the body 218a that is defined by the caps 218b. In addition, the caps 218b may be disposed to be spaced apart from the teeth 215c formed on the rotational body 215a. At this point, the cap 218b disposed at a location to which the grooves 215b filled with the organic material moves is disposed to the spaced apart from the grooves 215b so that a conveyer 217 can be inserted into the space. Further, the cap 218b located at a location away from which the grooves 215b filled with the organic material rotate may be disposed to have a minimum gap space with an outer circumference of the teeth 215a.

The fixed-quantity support 216b serves to fill the organic material in the grooves 215b of the material flow controller 215 as much as the volume of the groove 215b. The fixed-quantity support 216b is connected to a support 216a coupled to an end portion of the first pipe 212 in the rotational space of the body 218a. At this point, the fixed-quantity support 216b is disposed under the first pipe 212 in the rotational space of the body 218a. Here, the fixed-quantity support 216b is disposed above one of the teeth 215c, which is located under an end portion of the first pipe 212. At this point, the fixed-quantity support 216b may be disposed above the tooth 215c located at a location to which the grooves 215b filled with the organic material move. Further, the fixed-quantity support 216b is disposed to closely contact the teeth 215c and the grooves 215b that move under the fixed-quantity support 216b. In this embodiment, as shown in FIG. 8, the grooves 215b receiving the organic material from the first pipe 212 rotate clockwise by rotating the rotational body 215a clockwise. At this point, the fixed-quantity support 216b is disposed above the tooth 215c located at an immediately right side of the first pipe 212. Needless to say, the present invention is not limited to this. For example, when rotating counterclockwise, the fixed-quantity support 216b is located above the teeth 215c that is located at an immediately left side of the first pipe 212. In addition, the fixed-quantity support 216b may be horizontally disposed to the tops of the teeth 215c formed on the rotational body 215a. A lower end of the fixed-quantity support 216b may contact the top of the teeth 215c. Therefore, the lower end of the fixed-quantity rakes out the organic material that is accumulated in the groove 215b to be higher than teeth 215c while the groove 215b passes through the fixed-quantity support 216b by the rotation of the rotational body 215a of the material flow controller 215. At this same time, the organic material accumulated on the top of the teeth 215c of the material flow controller 215 by a predetermined thickness is also raked out by the fixed-quantity support 216b.

The conveyer 217 functions to allow the organic material filled in the groove 215b rotates to move above the second pipe 215 without any loss. As shown in FIG. 11, such a conveyer 217 includes a belt 217a and rolling rods 217b connected to opposite ends of the belt 217a. Further, although not shown in the drawings, the conveyer 217 further includes a fixing unit for fixing the rolling rods 217b.

The belt 217a is disposed between the fixed-quantity support 216b and the second pipe 215. That is, the belt 217a may be disposed at a location to which at least one of the grooves 215b of the material flow controller 215 filled with the organic material moves. At this point, the belt 217a is disposed in a space defined between the cap 218b and the teeth 215c. Further, the belt 217a may be disposed to enclose the tooth 215c and the grooves 215b by closely contacting the teeth 215c. Accordingly, the belt 217a rotates, when the rotational body 215a rotates, together with the teeth 215c. Here, the rolling rods 217b are disposed at the opposite ends of the belt 217a. That is, the rolling rods 217b are respectively disposed at a first location S1 adjacent to the fixed-quantity support 216b and a second location S2 adjacent to the second pipe 215. Accordingly, when the rotational body 215a rotates, the belt 217a rotates while circulating between the first and second locations S1 and S2 at which the rolling rods 217b are disposed. Accordingly, a fixed amount of the organic material that are filled to a level of the teeth 215c can be transferred right above the second pipe 215 without any loss. Here, the belt 217a of the conveyer 217 may be formed of a polymer material such as Teflon.

The rolling rods 217b are formed in a cylindrical pipe shape. At this point, the fixing units (not shown) are disposed through hollow portions of the rolling rods 217b. The fixing units are supported on an end portion of the body 218a of the material flow controller 215. Therefore, the rolling rods 217b are supported on opposite ends of the belt 217a.

The following will describe the operation of the deposition material supplying unit 210 in accordance with the exemplary embodiment of FIGS. 7 through 9.

First, the powder type organic material stored in the canister 211 is supplied to the grooves 215b of the material flow controller 215 through the first pipe 212. At this point, the driving unit 214 controls the RPM of the rotational body 215a and thus controls an amount of the organic material filled in the grooves 215b. Next, the driving unit 214 rotates the rotational body 215a clockwise such that the grooves 215b filled with the organic metal sequentially pass through the fixed-quantity support 216b, in the course of which the fixed-quantity support rakes out the organic material projecting above the tops of the teeth 215c. Therefore, the organic material is filled in the grooves 215b as much as the volume of the grooves 215b. In addition, by continuously rotating the rotational body 215a, the grooves 215b that are not filled with the organic material are continuously exposed to the first pipe 212 and thus the organic material of the first pipe 212 is continuously supplied to at least one of the grooves 215b of the material flow controller 215.

Next, the grooves 215b filled with the organic material moves toward the belt 217a of the conveyer 217. At this point, the belt 217a covers the tops of the grooves 215b moved to a rear surface of the belt 217a. Therefore, the removal of the organic material from the grooves 215b can be prevented by the belt 217a. In addition, as the rotational body 215a provided with the teeth 215c rotates, the belt 217a engaged with the teeth 215c rotates. Here, the belt 217a rotates while circulating based on the rolling rods 217b located at the respective first and second locations S1 and S2 at the opposite ends of the belt 217a.

Further, the grooves 215b filled with the organic material are sequentially exposed by continuously rotating the rotational body 215a of the material supplying unit, after which the carrier gas is supplied through the gas supplying pipe 213 connected to the carrier gas supplying unit 230. Therefore, the carrier gas is injected to the groove 215b filled with the organic material and disposed immediately above the second pipe 215. As a result, the organic material filled in the groove 215b is separated from the groove 215b by the injected carrier gas and moves into the fourth pipe P4 via the second pipe 215. Since the fourth pipe P4 communicates with the injection unit 130 in the depositing apparatus 100, the organic material in the fourth pipe P4 moves the injection unit 130.

Next, using the identical process to the above, another groove 215b filled with the organic material is exposed to the second pipe 215 by rotating the rotational body 215a and the organic material filled in the groove 215b is supplied to the injection unit 130 in the chamber 110.

As described above, in this embodiment, the organic material is transferred not using the pressure difference but using a mechanical or physical method using the material flow controller 215. Therefore, a fixed amount of the organic material can be supplied to the depositing apparatus 100 without being affected by a property of the deposition material and surrounding environments. Further, by rotating the rotational body 215a using the driving unit 214 of the material flow controller 21, a fixed amount of the organic material can be continuously supplied to the injection unit in the chamber 110.

Although the description is made on the organic material in the exemplary embodiments, the present invention is not limited to this. Other power type materials that can be deposited may be also used.

According to the present invention, the deposition material is filled in the groove and a fixed amount of the deposition material is supplied into the process chamber using the deposition material flow controller. Therefore, it is easy to control an amount of the deposition material supplied to the process chamber and the reliability on the fixed-quantity supply can be improved.

Although the deposition material supplying module and the thin film deposition system have been described with reference to the specific embodiments, they are not limited thereto. Therefore, it will be readily understood by those skilled in the art that various modifications and changes can be made thereto without departing from the spirit and scope of the present invention defined by the appended claims.

What is claimed is:

1. A deposition material supplying module comprising:
a canister comprising a storage space in which a deposition material is stored;
a material flow controller which comprises at least one groove receiving the deposition material supplied from the canister and is configured to be rotatable; and
a carrier gas supplying unit configured to supply carrier gas to the material flow controller.

2. The deposition material supplying module of claim 1, wherein the material flow controller comprises a rotational body and the groove is provided at a side of the rotational body.

3. The deposition material supplying module of claim 1, wherein the material flow controller comprises a rotational body; a plurality of teeth formed on the rotational body and spaced apart from each other; and a plurality of grooves disposed between the teeth.

4. The deposition material supplying module of claim 2, wherein the material flow controller is disposed in a pipe which comprises a rotating space in which the material flow controller rotates and connects the canister to a deposition apparatus.

5. The deposition material supplying module of claim 4, wherein one end of the pipe is connected to the canister and the other end is connected to the deposition apparatus.

6. The deposition material supplying module of claim 5, further comprising a carrier gas supplying pipe that is coupled to a side of the pipe to inject the carrier gas of the carrier gas supplying unit to the groove of the material flow controller.

7. The deposition material supplying module of claim 6, wherein the material flow controller is installed at an intersection region of the pipe and the carrier gas supplying pipe in the rotating space of the pipe.

8. The deposition material supplying module of claim 3, wherein the teeth are formed on an outer circumference of the rotational body and spaced apart from each other at predetermined intervals to define the grooves between the teeth.

9. The deposition material supplying module of claim 3, wherein the grooves are formed at an outer circumference and spaced apart from each other at predetermined intervals to define the teeth between the grooves.

10. The deposition material supplying module of claim 3, wherein the material flow controller is disposed in a body provided with a rotating space, and the canister storing the deposition material is disposed above the material flow controller in the body.

11. The deposition material supplying module of claim 10, further comprising a first pipe connecting the canister to the material flow controller and a second pipe disposed under the material flow controller and communicating with a deposition apparatus.

12. The deposition material supplying module of claim 11, further comprising a carrier gas supplying pipe that is coupled to a side of the second pipe to supply the carrier gas of the carrier gas supplying unit to the groove of the material flow controller.

13. The deposition material supplying module of claim 11, further comprising a fixed-quantity support that is disposed over the teeth of the material flow controller under an end portion of the first pipe, and configured to allow the deposition material to be filled in the groove as much as a volume of the groove.

14. The deposition material supplying module of claim 13, wherein the fixed-amount support is disposed at a location toward which at least one of the grooves of the material flow controller filled with the deposition material moves and the tooth and groove moves immediately under the fixed-quantity support such that tops of the tooth and groove closely contact the fixed-quantity support.

15. The deposition material supplying module of claim 3, further comprising a conveyer that is disposed to cover at least some of the teeth and grooves formed on the rotational body.

16. The deposition material supplying module of claim 15, wherein the conveyer comprises a belt and rolling rods disposed at opposite ends of the belt.

17. The deposition material supplying module of claim 16, wherein the belt rotates while circulating based on the rolling rods disposed on the opposite ends of the belt.

18. The deposition material supplying module of claim 17, wherein the belt is disposed at a location toward which at least one of the grooves of the material flow controller filled with the deposition material moves and is configured to rotate together with the rotational body by closely contacting the teeth formed on the rotational body.

19. The deposition material supplying module of claim 1, further comprising: at least one of an agitator and a vibrator that is disposed in the canister to agitate the deposition material; and a filter configured to uniformly control an amount of the deposition material supplied from the canister to the material flow controller.

20. The deposition material supplying module of claim 19, wherein the agitator comprises:
a power unit formed at a side of the canister;
a shaft connected to the power unit; and
one or more blades formed in a direction intersecting the shaft and spaced apart from each other.

21. The deposition material supplying module of claim 1, wherein the material flow controller is connected to a driving unit comprising a rotational shaft connected to the rotational body and a rotating member configured to rotate the rotational shaft.

22. A thin film deposition system comprising:
a deposition apparatus configured to deposit a thin film; and
a deposition material supplying module configured to supply a deposition material to the deposition apparatus,
wherein the deposition material supplying module comprises:
a canister comprising a storage space in which a deposition material is stored;
a material flow controller which comprises at least one groove receiving the deposition material supplied from the canister and is configured to be rotatable; and
a carrier gas supplying unit configured to supply carrier gas to the material flow controller.

23. The thin film deposition system of claim 22, further comprising a carrier gas storage unit configured to store the carrier gas and supply the carrier gas to the carrier gas supplying unit.

24. The thin film deposition system of claim 23, further comprising a first pipe for connecting the carrier gas storage unit to the carrier gas supplying unit, second and third pipes for connecting the carrier gas supplying unit to the deposition material supplying module, and a first valve for controlling communication between the second and third pipes.

25. The thin film deposition system of claim 24, further comprising fourth and fifth pipes for connecting the deposition material supplying module to the deposition apparatus and a second valve for controlling communication between the fourth and fifth pipes.
